(19) United States
(12) Patent Application Publication
(10) Pub. No.: US 2026/0219584 A1
(43) Pub. Date: Jul. 30, 2026

(54) SYSTEM FOR CHANGING THE SHAPE OF A SUBSTRATE

(71) Applicant: ASML NETHERLANDS B.V., Veldhoven (NL)

(72) Inventors: Adrianus Hendrik KOEVOETS, Mierlo (NL); Dennis Dominic VAN DER VOORT, Best (NL)

(73) Assignee: ASML NETHERLANDS B.V., Veldhoven (NL)

(21) Appl. No.: 19/149,005

(22) PCT Filed: Jan. 11, 2024
(86) PCT No.: PCT/EP2024/050612

§ 371 Date: Jul. 17, 2025

(30) Foreign Application Priority Data
Feb. 10, 2023 (EP) 23156107.7

(51) Int. Cl. G03F 7/00; H10P 72/72

(52) U.S. Cl. CPC G03F 7/70708; G03F 7/70525; G03F 7/7085; H10P 72/722

(57) ABSTRACT

A substrate support arrangement configured to support a substrate, the substrate support arrangement including: a substrate support with a substantially planar support surface for a substrate; and a substrate shaping system that includes one or more substrate shaping devices, wherein each substrate shaping device is moveable relative to the substrate support; and wherein, when a substrate is provided on the support surface, each substrate shaping device is arranged to apply an electrostatic force to the periphery of the substrate.

### CROSS-REFERENCE TO RELATED APPLICATIONS

This application claims priority of EP Application Serial No. 23156107.7 which was filed on 10 Feb. 2023 and which is incorporated herein in its entirety by reference.

### FIELD

The present invention relates to techniques for changing the shape of a substrate. Electrostatic forces may be applied to the periphery of a substrate W to at least partially reduce the shape deformation of the substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask or reticle) onto a layer of radiation-sensitive material (resist) provided on a substrate.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features.

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

In a conventional lithography apparatus, the substrate to be exposed may be supported by a substrate support (i.e. the object that directly supports a substrate) which in turn is supported by a substrate table (mirror block or stage, i.e. the object such as table that supports the substrate support and provides the upper surface surrounding the substrate support). The substrate support is often a flat rigid disc corresponding in size and shape to the substrate (although it may have a different size or shape). It has an array of projections, referred to as burls or pimples, projecting from at least one side. The substrate support may have an array of projections on two opposite sides. In this case, when the substrate support is placed on the substrate table, the main body of the substrate support is held a small distance above the substrate table while the ends of the burls on one side of the substrate support lie on the surface of the substrate table. Similarly, when the substrate rests on the top of the burls on the opposite side of the substrate support, the substrate is spaced apart from the main body of the substrate support. The purpose of this is to help prevent a particle (i.e. a contaminating particle such as a dust particle) which might be present on either the substrate table or substrate support from distorting the substrate support or substrate. Since the total surface area of the burls is only a small fraction of the total area of the substrate or substrate support, it is highly probable that any particle will lie between burls and its presence will have no effect. Often, the substrate support and substrate are accommodated within a recess in the substrate table so that the upper surface of the substrate is substantially coplanar with the upper surface of the substrate table.

Due to the high accelerations experienced by the substrate in use of a high-throughput lithographic apparatus, it is not sufficient to allow the substrate simply to rest on the burls of the substrate support. It is clamped in place. Two methods of clamping the substrate in place are known—vacuum clamping and electrostatic clamping. In vacuum clamping, the space between the substrate support and substrate and optionally between the substrate table and substrate support are partially evacuated so that the substrate is held in place by the higher pressure of gas or liquid above it. Vacuum clamping however may not be used where the beam path and/or the environment near the substrate or substrate support is kept at a low or very low pressure, e.g. for extreme ultraviolet (EUV) radiation lithography. In this case, it may not be possible to develop a sufficiently large pressure difference across the substrate (or substrate support) to clamp it. Electrostatic clamping may therefore be used. In electrostatic clamping, a potential difference is established between the substrate, or an electrode plated on its lower surface, and an electrode provided on, or in, the substrate table and/or substrate support. The two electrodes behave as a large capacitor and substantial clamping force can be generated with a reasonable potential difference. An electrostatic arrangement can be such that a single pair of electrodes, one on the substrate table and one on the substrate, clamps together the complete stack of substrate table, substrate support and substrate. In a known arrangement, one or more electrodes may be provided on, or in, the substrate support so that the substrate support is clamped to the substrate table and the substrate is separately clamped to the substrate support.

There is a need to improve substrate supports that comprise one or more electrostatic clamps for clamping a substrate support to a substrate table and/or a substrate to a substrate support. More generally, there is a need to improve an object holder, such as patterning device holder, that comprises one or more electrostatic clamps for holding the object holder to a table and/or holding an object against the object holder.

### SUMMARY

According to a first aspect of the invention, there is provided a substrate support arrangement configured to support a substrate, the substrate support arrangement comprising: a substrate support with a substantially planar support surface for a substrate; and a substrate shaping system that comprises one or more substrate shaping devices; wherein each substrate shaping device is moveable relative to the substrate support; and wherein, when a substrate is provided on the support surface, each substrate shaping device is arranged to apply an electrostatic force to the periphery of the substrate.

According to a second aspect of the invention, there is provided a lithographic apparatus comprising the substrate support arrangement according to the first aspect.

According to a third aspect of the invention, there is provided a method of changing the shape of a substrate, the method comprising: loading a substrate onto the substrate support of a substrate support arrangement according to the first aspect; and applying an electrostatic force to the periphery of the substrate.

### BRIEF DESCRIPTION OF THE DRAWINGS

Embodiments of the invention will now be described, by way of example only, with reference to the accompanying schematic drawings, in which:

FIG. 1 schematically depicts an EUV lithographic system comprising a lithographic apparatus and a radiation source;

FIG. 2 is a cross-sectional view of an object holder according to an embodiment of the invention;

FIG. 3 schematically depicts a DUV lithographic apparatus;

FIG. 4 schematically depicts, in cross-section, a substrate support;

FIG. 5 schematically depicts a substrate support arrangement for use in an EUV system according to a first embodiment;

FIG. 6 schematically shows a substrate support arrangement for use in a DUV system according to a second embodiment; and

FIG. 7 schematically shows part of a seal according to the second embodiment.

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

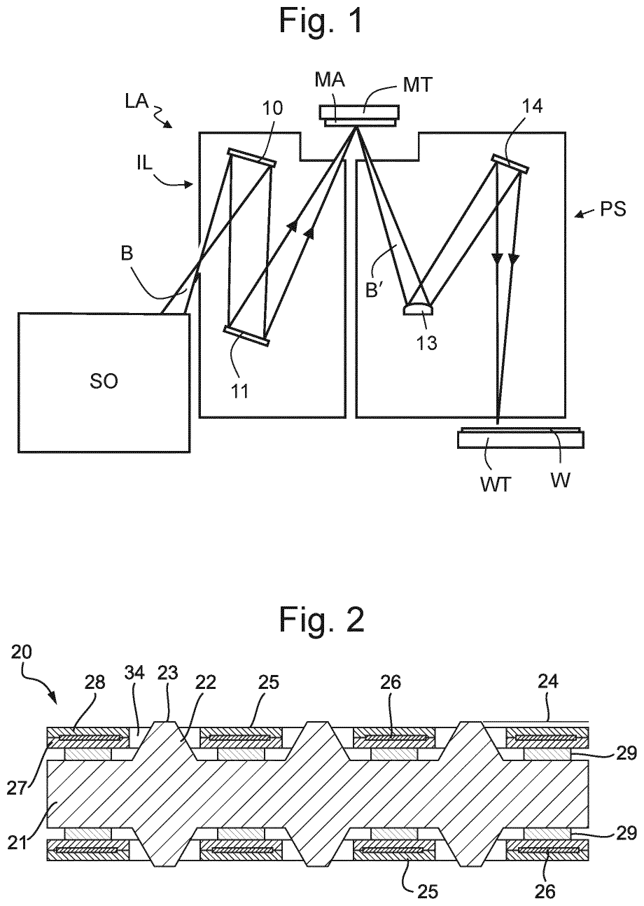

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask or reticle), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13, 14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

FIG. 2 is a cross-sectional view of a substrate support 20. The substrate support 20 is configured to support a substrate W.

The substrate table WT comprises the substrate support 20 and a substrate stage (not shown). The substrate stage comprises a recess into which the substrate support 20 is held. The substrate support 20 is configured to hold the substrate W relative to the substrate stage of the substrate table WT.

As shown in FIG. 2, the substrate support 20 comprises a support body 21. The support body 21 is a plate-like disk. As shown in FIG. 2, the support body 21 comprises a plurality of burls 22. The burls 22 are protrusions protruding at the surface of the support body 21. As shown in FIG. 2, the burls 22 have distal ends 23. The support body 21 is configured such that the distal ends 23 define a support plane 24 for supporting the substrate W. The underside of the substrate W comes into contact with the distal ends 23 of the burls 22. The position of the underside of the substrate W corresponds to the support plane 24. The burls 22 are arranged so that the substrate W lies generally flat on the substrate support 20.

The burls 22 are not shown to scale in FIG. 2. In a practical embodiment, there can be many hundreds, thousands, or tens of thousands, of burls 22 distributed across a substrate support 20 of diameter, e.g., 200 mm, 300 mm or 450 mm. The tips, i.e., distal ends 23 of the burls 22 have a small area, e.g. less than 1 mm², so that the total area of all of the burls 22 on one side of the substrate support 20 is less than about 10% of the total area of the total surface area of the substrate support 20. Because of the arrangement of burls 22, there is a high probability that any particle that might lie on the surface of the substrate W, substrate support 20 or substrate table WT will fall between burls 22 and will not therefore result in a deformation of the substrate W or substrate support 20. The burl arrangement, which may form a pattern, can be regular or can vary as desired to provide appropriate distribution of force on the substrate W and substrate table WT. The burls 22 can have any shape in plan but are commonly circular in plan. The burls 22 can have the same shape and dimensions throughout their height but are commonly tapered. The burls 22 can project a distance of from about 1 μm to about 5 mm, desirably from about 5 μm to about 250 μm, desirably about 10 μm above the rest of the object-facing surface of the substrate support 20 (i.e. the top surface of the electrostatic sheet 25). Hence, the distance between the distal ends 23 of the burls 22 and the top surface of the electrostatic sheet 25 in the vertical direction is from about 1 μm to about 5 mm, desirably from about 5 μm to about 250 μm, desirably about 10 μm. The thickness of the support body 21 of the substrate support 20 can be in the range of about 1 mm to about 50 mm, desirably in the range of about 5 mm to 20 mm, typically 10 mm.

The support body 21 may be made of rigid material. Desirably the material has a high thermal conductivity and a coefficient of thermal expansion that is close to that of the object held. Desirably the material is electrically conductive. Desirably the material has a high hardness. A suitable material includes SiC (silicon carbide), SiSiC (siliconized silicon carbide), Si₃N₄ (silicon nitrite), quartz, and/or various other ceramic and glass-ceramics, such as Zerodur™ glass ceramic. The support body 21 can be manufactured by selectively removing material from a solid disc of the relevant material so as to leave the projecting burls 22. A suitable technique to remove material includes electrical discharge machining (EDM), etching, machining and/or laser ablation. The support body 21 can also be manufactured by growing burls 22 through a mask. The burls 22 may be of the same material as the base and can be grown by a physical vapor deposition process or sputtering. The support body 21 may comprise one or more internal channels (not shown in the Figures). The support body 21 may comprise a plurality of layers that are bonded together. The layers may be formed of different materials. Merely as one example, in the support body 21 may comprise a layer of SiSiC, a layer of glass and another layer of SiSiC in that order. Other combinations of layers are also possible.

As shown in FIG. 2, the substrate support 20 may comprise one or more electrodes 26 for an electrostatic clamp. A potential difference may be generated in order to provide an electrostatic clamping force between the substrate W and the substrate support 20 and/or between the substrate support 20 and the substrate stage of the substrate table WT. The electrodes 26 may be encapsulated between dielectric layers 27, 28 (also known as electrical isolation layers). The potential difference generated may be of the order of 10 to 5,000 volts. Arrangements using one or more heaters and temperature sensors to locally control the temperature of a substrate are described in U.S. publication no. 2011-0222033, which is incorporated herein by reference in its entirety and the techniques therein may be applied to the techniques herein.

As shown in FIG. 2, the substrate support 20 may comprise an electrostatic sheet 25. The electrostatic sheet 25 comprises one or more electrodes 26. For the electrodes 26, two halves of continuous metal film (but isolated from the distal ends 23 of the burls 22) may be separated by a separation distance from each other and deposited to form positive and negative elements of the electrostatic clamp. The separation distance is not particularly limited. The separation distance may be at least about 20 μm, optionally at least about 50 μm, optionally at least about 100 μm, optionally at least about 200 μm, and optionally at least about 500 μm. The separation distance may be at most about 2 mm, optionally at most about 1 mm, and optionally at most about 500 μm. The separation distance may be about 500 μm. There may therefore be two electrodes 26. However, the number of electrodes 26 in the electrostatic sheet 25 is not particularly limited and may be one or three or more. Metal lines of the electrodes 26 may have a layer thickness greater than about 20 nm, desirably greater than about 40 nm. The metal lines desirably have a layer thickness less than or equal to about 1 μm, desirably less than about 500 nm, desirably less than about 200 nm.

An electrode 26 of an upper electrostatic sheet 25 may be configured to electrostatically clamp the substrate W to the substrate support 20. An electrode 26 of a lower electrostatic sheet 25 may be configured to electrostatically clamp the substrate support 20 to the rest, e.g., substrate stage of the substrate table WT.

The material of the support body 21 and the burls 22 may be electrically conductive. For example, the material of the burls 22 may be SiSiC. However, it is not essential for the material of the support body 21 and the burls 22 to be electrically conductive. A grounding layer may be provided that electrically connects the distal ends 23 of two or more of the burls 22 (optionally all of the burls 22) to ground or a common electrical potential. The grounding layer may be formed by depositing a relatively thick layer of a conductive material. The conductive material is not particularly limited. The conductive material may be Cr or CrN. The deposited layer may then be patterned to form the grounding layer. The pattern may comprise a series of metal lines that connect together distal ends 23 of the burls 22. Such patterns are sometimes referred to as “Manhattan” patterns. In an alternative arrangement the deposited layer is not patterned. The grounding layer or another layer may be arranged to cover a surface of the support body 21 and/or the burls 22. The grounding layer or other layer can help to smoothen the surface to make it easier to clean the surface.

As shown in FIG. 2, electrostatic sheet 25 may comprise an electrode 26 sandwiched between dielectric layers 27, 28. As shown in FIG. 2, burls 22 and the electrostatic sheet 25 may be provided on both main surfaces of the substrate support 20. In an alternative arrangement, the burls 22 and the electrostatic sheet 25 are provided on only one of the two main surfaces of the substrate support 20. As shown in FIG. 2, the electrostatic sheet 25 may be between the burls 22. For example, as shown in FIG. 2, holes 34 are provided in the electrostatic sheet 25. The holes 34 are arranged such that their position corresponds to the burls 22 of the support body 21. The burls 22 protrude through respective holes 34 of the electrostatic sheet 25 such that the electrode 26 that is sandwiched between the dielectric layers 27, 28 is provided in the region between the burls 22.

As shown in FIG. 2, the substrate support 20 may comprise a bonding material 29. The bonding material 29 may have a thickness of at least 100 nm, for example about 50 μm. The bonding material 29 secures the position of the electrostatic sheet 25 relative to the support body 21. The bonding material 29 keeps the holes 34 in the electrostatic sheet 25 aligned with the burls 22. The burls 22 may be positioned at the centre of respective holes 34 of the electrostatic sheet 25.

As shown in FIG. 2, the bonding material 29 may be formed in discrete portions that do not connect to each other. There may be some variation in the thickness of the different portions of bonding material 29. The separate portions of bonding material 29 may have substantially the same thickness as each other.

As described above, the substrate table WT comprises the substrate support 20 and a substrate stage. The substrate stage comprises a recess into which the substrate support 20 is held. The substrate support 20 and substrate stage may be referred to as a substrate table WT.

Described above is a substrate support 20 for use in an EUV lithographic system. The configuration of a substrate in a DUV system is described below.

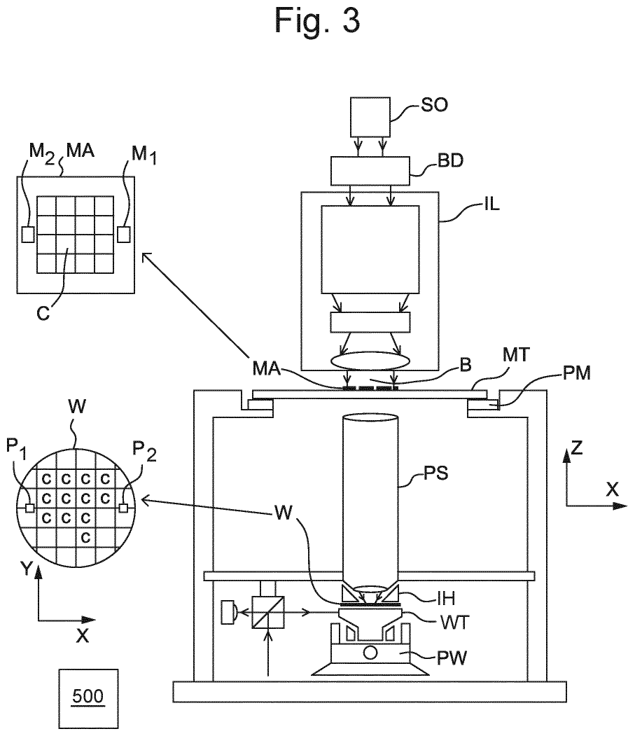

FIG. 3 schematically depicts a lithographic apparatus. The lithographic apparatus includes an illumination system (also referred to as illuminator) IL configured to condition a radiation beam B (e.g., UV radiation or DUV radiation), a support structure (e.g., a mask table) MT constructed to support a patterning device (e.g., a mask) MA and connected to a first positioner PM configured to accurately position the patterning device MA in accordance with certain parameters, a substrate table WT, optionally comprising a substrate support, constructed to hold a substrate (e.g., a resist coated wafer) W and connected to a second positioner PW configured to accurately position the substrate table WT in accordance with certain parameters, and a projection system PS (e.g., a refractive projection lens system) configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W-which is also referred to as immersion lithography. More information on immersion techniques is given in U.S. Pat. No. 6,952,253, which is incorporated herein by reference.

The lithographic apparatus may be of a type having two or more substrate tables WT (also named “dual stage”). In such a “multiple stage” machine, the substrate tables WT may be used in parallel, and/or steps in preparation of a subsequent exposure of the substrate W may be carried out on the substrate W located on one of the substrate table WT while another substrate W on the other substrate table WT is being used for exposing a pattern on the other substrate W.

In addition to the substrate table WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device MA, e.g. mask, which is held on the support structure MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate table WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the present description, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the present description and is used for clarification only. Instead, another coordinate system, such as a cylindrical coordinate system, may be used to clarify the present description. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in an immersion space between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space between the final element and a surface facing the final element. The facing surface is a surface of substrate W or a surface of the supporting stage (or substrate table WT or substrate support) that is co-planar with the surface of the substrate W. (Please note that reference in the following text to surface of the substrate W also refers in addition or in the alternative to the surface of the substrate table WT or substrate support, unless expressly stated otherwise; and vice versa). A fluid handling structure IH present between the projection system PS and the substrate table WT or substrate support is used to confine the immersion liquid to the immersion space. The immersion space filled by the immersion liquid is smaller in plan than the top surface of the substrate W and the immersion space remains substantially stationary relative to the projection system PS while the substrate W and substrate support move underneath.

Other immersion systems have been envisaged such as an unconfined immersion system (a so-called ‘All Wet’ immersion system) and a bath immersion system. In an unconfined immersion system, the immersion liquid covers more than the surface under the final element. The liquid outside the immersion space is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space, removes the immersion liquid from the immersion space and thereby confines the immersion liquid to the immersion space. It includes features which are a part of a fluid supply system. The arrangement disclosed in PCT patent application publication no. WO 99/49504 is an early fluid handling structure comprising pipes which either supply or recover the immersion liquid from the immersion space and which operate depending on the relative motion of the stage beneath the projection system PS. In more recent designs, the fluid handling structure extends along at least a part of a boundary of the immersion space between the final element of the projection system PS and the substrate support WT or substrate W, so as to in part define the immersion space.

The fluid handing structure IH may have a selection of different functions. Each function may be derived from a corresponding feature that enables the fluid handling structure IH to achieve that function. The fluid handling structure IH may be referred to by a number of different terms, each referring to a function, such as barrier member, seal member, fluid supply system, fluid removal system, liquid confinement structure, etc.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 3, the lithographic apparatus comprises a controller 500. The controller 500 is configured to control the substrate table WT.

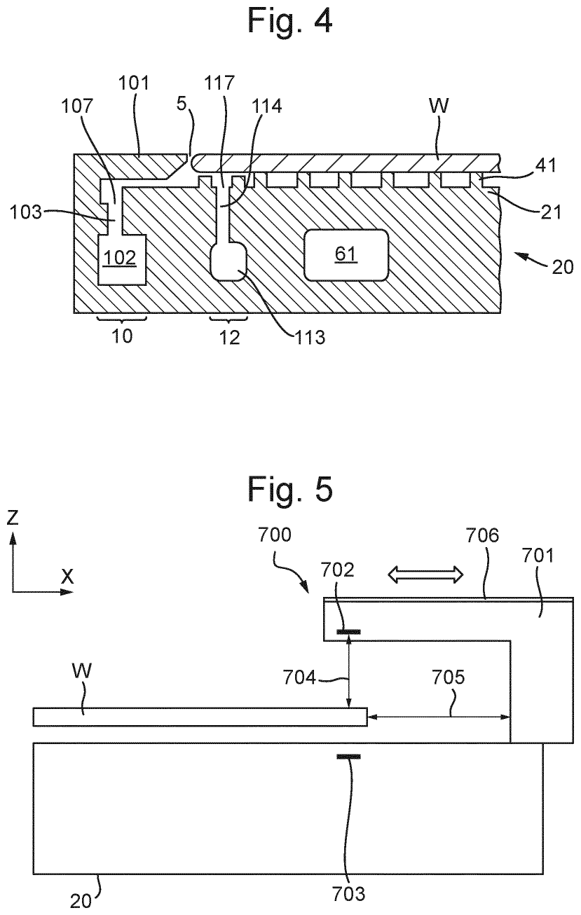

FIG. 4 illustrates part of a lithographic apparatus that is not in accordance with the present invention, but is useful for demonstrating features of the present invention. The arrangement illustrated in FIG. 4 and described below may be applied to the lithographic apparatus described above and illustrated in FIG. 3. FIG. 4 is a cross-section through a substrate support 20 and a substrate W. The substrate table WT of FIG. 3 may comprise the substrate support 20 and a substrate stage (not shown) configured to support the substrate support 20 or the substrate support 20 itself may be integral with the substrate table WT forming a single piece. In an embodiment, the substrate support 20 comprises one or more conditioning channels 61 of a thermal conditioner 60, which is described in more detail below. A gap 5 exists between an edge of the substrate W and an edge of the substrate support 20. When the edge of the substrate W is being imaged or at other times such as when the substrate W first moves under the projection system PS (as described above), the immersion space filled with liquid by the fluid handling structure IH (for example) will pass at least partly over the gap 5 between the edge of the substrate W and the edge of the substrate support 20. This can result in liquid from the immersion space entering the gap 5.

The substrate W is held by a support body 21 (e.g. a pimple or burl table) comprising one or more burls 41 (i.e., projections from the surface). The support body 21 is an example of an object holder. Another example of an object holder is a support structure MT. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In FIG. 4 two drains 10, 12 are illustrated, though there may only be one drain or there could be more than two drains. Each of the drains 10, 12 is annular so that the whole periphery of the substrate W is surrounded.

A primary function of the first drain 10 (which is radially outward of the edge of the substrate W/support body 21) is to help prevent bubbles of gas from entering the immersion space where the liquid of the fluid handling structure IH is present. Such bubbles may deleteriously affect the imaging of the substrate W. The first drain 10 is present to help avoid gas in the gap 5 escaping into the immersion space in the fluid handling structure IH. If gas does escape into the immersion space, this can lead to a bubble which floats within the immersion space. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. The cover ring 101 may be shaped, in plan, as a ring and surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 4, in an embodiment the lithographic apparatus comprises a first extraction channel 102 for the passage therethrough of a two phase flow. The first extraction channel 102 is formed within the support body 21. The first and second drains 10, 12 are each provided with a respective opening 107, 117 and a respective extraction channel 102, 113. The extraction channel 102, 113 is in fluid communication with the respective opening 107, 117 through a respective passageway 103, 114.

As depicted in FIG. 4, the cover ring 101 has an upper surface. The upper surface extends circumferentially around the substrate W on the support body 21. In use of the lithographic apparatus, the fluid handling structure IH moves relative to the substrate support 20. During this relative movement, the fluid handling structure IH moves across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment the relative movement is provided by movement of both the substrate support 20 under the fluid handling structure IH and movement of the fluid handling structure IH over the substrate support 20. In the following description, movements of the fluid handling structure IH will be used to mean the relative movement of the fluid handling structure IH relative to the substrate support 20.

In both EUV and DUV systems, a substrate W, that is held on a substrate support 20, may be warped. That is to say, the shape of the substrate W is deformed so that it is not perfectly planar. Typical shape deformations of a substrate W are bowl shaped and umbrella shaped. Such shape deformations of a substrate W may be at least partially corrected by movement of part of the substrate W in the z-direction, either towards or away from the substrate support 20. However, there is currently no known technique for quickly providing such movement outside of the last burl row. The shape deformation at the periphery, i.e. edge region, of a substrate W may therefore be a substantial cause of overlay error.

Embodiments solve the above problem by providing a new technique for moving the periphery of a substrate W in the z-direction to at least partially correct for the shape deformation of the substrate W.

FIG. 5 schematically shows a substrate support arrangement for use in an EUV system according to a first embodiment.

The substrate support arrangement comprises a substrate support 20 and a substrate shaping system 700. The substrate support 20 may be the above-described substrate support 20 with reference to FIGS. 1 and 2. The substrate support 20 may provide a support plane that is a substantially planar support surface for a substrate W. As described earlier with reference to the support plane 24 in FIG. 2, the support surface 24 may be provided by the distal ends 23 of a plurality of burls 22.

The substrate shaping system 700 comprises at least one substrate shaping device 701. When a substrate W is provided on the support surface, each substrate shaping device 701 is arranged to apply an electrostatic force to the periphery of the substrate W. Each substrate shaping device 701 may comprise an electrode arrangement that is configured to generate the electrostatic force applied to the substrate W by the substrate shaping device 701. Each electrode arrangement may comprise a ground electrode 706 and a force generating electrode 702. As shown in FIG. 5, the ground electrode 706 may be provided on, or embedded within, an upper surface of part of the substrate shaping device 701. The force generating electrode 702 may be provided on, or embedded within, an lower surface of part of the substrate shaping device 701. The force generating electrode 702 may be located above a substrate W so that the applied electrostatic force moves the substrate W away from the substrate support 20. The electrostatic force applied to the substrate W may generated by the potential difference between the force generating electrode 702 and the substrate W. The substrate support arrangement may also comprise a controller (not shown) that is arranged to control the magnitude of a potential difference between the ground electrode 706 and the force generating electrode 702. The magnitude of the electrostatic force applied by the force generating electrode 702 may be dependent on the potential difference between the ground electrode 706 and the force generating electrode 702. The controller may thereby control the magnitude of the electrostatic force applied to the substrate W.

The substrate shaping system 700 may comprise a plurality of substrate shaping devices 701. In plan view, the plurality of substrate shaping devices 701 may be arranged around the support surface. The plurality of substrate shaping devices 701 may be equally spaced around the circumference of the support surface. Each substrate shaping device 701 may be arranged to apply an electrostatic force to a different segment of a substrate W. The substrate shaping devices 701 may be independently controllable. The substrate shaping devices 701 may thereby be arranged to independently apply electrostatic forces to different parts of the periphery of the substrate W.

Each substrate shaping device 701 may be moveable between a first position and a second position. In the first position, a substrate shaping device 701 may be located close to and above the periphery of a substrate W. An electrostatic force is a short range force. Positioning the substrate shaping device 701 close to and above the periphery of a substrate W ensures that the electrostatic force is applied to the periphery of the substrate W. The central region of the substrate W may be substantially unaffected by the electrostatic forces due to its increased distance from the force generating electrodes 702.

When each substrate shaping device 701 is in its first position, it may be difficult to load a substrate W on to the substrate support 20 due to the risk of a collision between the substrate W and at least one substrate shaping device. To solve this problem, each substrate shaping device 701 may be movable to a second position in which each substrate shaping device 701 may be located further away from a mid-point of the substrate support 20. When each substrate shaping device 701 is in its second position, a substrate W may be easily positioned on the substrate support 20. Each substrate shaping device 701 may therefore be moved to its second position during the loading and unloading of a substrate W, and moved to its first position when a substrate W is loaded on the substrate support 20.

FIG. 5 schematically shows a substrate shaping device 701 in the first position. The substrate shaping device 701 may be comprised by a substantially L-shaped part of the substrate shaping system 700. When in the first position, the substrate shaping device 701 may be arranged to overhang the periphery of the substrate W. There is a x-y-directed separation distance 705, that may be referred to as a lateral gap, between the edge of the substrate W and a vertical stem of the substrate shaping device 701. There is a z-directed separation distance 704, that may be referred to as a vertical gap, between the upper surface of the substrate W at the periphery of the substrate W and the overhanging substrate shaping device 701.

For movement between the first and second positions, each substrate shaping device 701 may be moveable relative to the substrate support 20 in a direction parallel to the plane of the support surface, i.e. in a direction that increases, or decreases, the x-y-directed separation distance 705. Each substrate shaping device 701 may additionally, or alternatively, be moveable relative to the substrate support 20 in a direction perpendicular to the plane of the support surface, i.e. in a direction that increases, or decreases, the z-directed separation distance 704. The substrate shaping system 700 may comprise one or more piezoelectric actuators (not shown) for moving each substrate shaping device 701 relative to the substrate support 20.

When each substrate shaping device 701 is located in its first position, its force generating electrode 702 is arranged such that the applied electrostatic force to a substrate W comprises a component that is perpendicular to the plane of the support surface and is directed so as to move the substrate W away from the support surface. The force generating electrode 702 may be located directly above the upper surface of the substrate W at the periphery of the substrate W so that the electrostatic force is directed at an angle of about 90° to the plane of the support surface. Alternatively, the force generating electrode 702 may be located above and also laterally away from the upper surface of the substrate W at the periphery of the substrate W so that the electrostatic force is directed at an angle of about 80° to the plane of the support surface.

The first position of each substrate shaping device 701 may be changed in dependence of the actual shape of the current substrate W that is loaded on the substrate support 20. The type of the substrate shape deformation that may need to be corrected may be bowl shaped or umbrella shaped. The extent of the substrate shape deformation will also vary between substrates W. If the first position of each substrate shaping device is a fixed predetermined location that is used for all substrates W, then, due to the variations in the actual shapes of substrates W, each substrate shaping device 701 may not be located sufficiently close to the surface of the substrate W. Accordingly, so as to ensure that the first position of each substrate shaping device 701 is sufficiently close to the surface of the substrate W, the first position of each substrate shaping device 701 may be determined in dependence of the actual shape of the current substrate W that is loaded on the substrate support 20.

In order to determine an appropriate first position for each substrate shaping device 701, the substrate shaping system 700 may comprise a sensor system (not shown) configured to determine the relative position of each substrate shaping device 701 and the substrate W. For example, the sensor system may determine the magnitude of the x-y-directed separation distance 705 and/or the z-directed separation distance 704. The sensor system may comprise one or more capacitors and/or light sources for determining/measuring the magnitude of the x-y-directed separation distance 705 and/or the z-directed separation distance 704.

An appropriate first position of each substrate shaping device 701 may be determined as a location at which the magnitude of the x-y-directed separation distance 705 and/or the z-directed separation distance 704 are within predetermined ranges. For example, the movement of each substrate shaping device 701 may be controlled, by a controller, so that its x-y-directed separation distance 705 is less than or equal to 10 μm, and its z-directed separation distance 704 is less than or equal to 10 μm.

The above-described substrate shaping system 700 applies electrostatic forces to the periphery of a substrate W with the applied electrostatic forces moving the substrate W away from the substrate support 20.

Embodiments also include techniques for applying electrostatic forces to the periphery of a substrate W with the applied electrostatic forces moving the substrate W towards the substrate support 20.

As shown in FIG. 5, embodiments include providing one or more further force generating electrodes 703. Each of the one or more further force generating electrodes 703 may be provided on the surface of, or embedded in, the substrate support 20 and/or a surrounding structure of the substrate support 20. The one or more further force generating electrodes 703 may be positioned so that, when a substrate W is loaded on the substrate support 20, the one or more further force generating electrodes 703 are located below the periphery of the substrate W. There may be a plurality of the further force generating electrodes 703. In plan view, the plurality of further force generating electrodes 703 may be arranged around the support surface. The plurality of further force generating electrodes 703 may be equally spaced around the circumference of the support surface. Each further force generating electrode 703 may be arranged to apply an electrostatic force to a different segment of a substrate W. The plurality of further force generating electrodes 703 may be independently controllable. The further force generating electrodes 703 may thereby be arranged to independently apply electrostatic forces to different parts of the periphery of the substrate W.

Each of the one or more further force generating electrodes 703 may be electrically insulated. The substrate support 20 and/or a surrounding structure of the substrate support 20 may be electrically grounded. For each of the one or more further force generating electrodes 703, a potential difference may be generated between the force generating electrode 703 and ground. Each further force generating electrode 703 may apply an electrostatic force to the substrate W with the applied force being dependent on the potential difference. A controller (not shown) may control each potential difference to thereby control the applied electrostatic force by each of the one or more further force generating electrodes 703.

Accordingly, the one or more further force generating electrodes 703 may generate electrostatic forces for moving the substrate W towards the substrate support 20.

Advantageously, the first embodiment provides techniques for moving the periphery of a substrate W towards and/or away from the plane of the support surface for the substrate W. Any shape deformation at the edges of a substrate W may thereby be a least partially corrected by applying forces to the substrate W for correcting this. The applied forces may be substantially perpendicular to the support plane of the substrate W. This avoids substantial lateral forces being applied to the substrate W. The use of electrostatic forces is preferable over contacting a substrate W to directly apply a mechanical force. Such direct contact with the substrate W may damage the substrate W.

According to a second embodiment, there is provided a technique for changing the shape of a substrate W in a DUV system in order to at least partially correct the shape deformation of the substrate W. In a similar manner to the first embodiment, the second embodiment also uses force generating electrodes to apply electrostatic forces to the periphery of a substrate W.

In a DUV system there is immersion fluid present between at least part of the surface of the substrate W and a projection system PS. If the immersion fluid flows into a region between a force generating electrode and the substrate W, the immersion fluid would substantially attenuate the electrostatic force applied to the substrate W. The second embodiment comprises at least one seal for ensuring that there is substantially no immersion fluid between each force generating electrode and the substrate W.

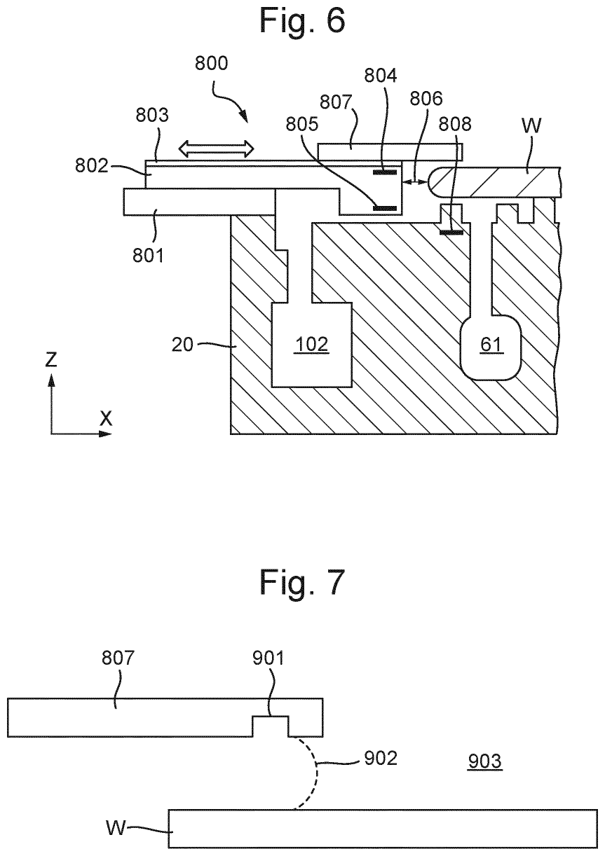

FIG. 6 schematically shows a substrate support arrangement for use in a DUV system according to the second embodiment.

The substrate support arrangement comprises a substrate support 20 and a substrate shaping system 800. The substrate support 20 may be the above-described substrate support 20 with reference to FIGS. 3 and 4. The substrate support 20 may provide a support plane that is a substantially planar support surface for a substrate W. The support surface may be defined by the distal ends of a plurality of burls 41.

The substrate shaping system 800 comprises at least one substrate shaping device 802 and at least one base 801. When a substrate W is provided on the support surface, each substrate shaping device 802 is arranged to apply an electrostatic force to the periphery of the substrate W. Each substrate shaping device 802 may comprise an electrode arrangement that is configured to generate the electrostatic force applied to the substrate W by the substrate shaping device 802. Each electrode arrangement may comprise a ground electrode 803 and at least one force generating electrode 804, 805. As shown in FIG. 6, each ground electrode 803 may be provided on, or embedded within, an upper surface of part of a substrate shaping device 802.

FIG. 6 shows an upper force generating electrode 804 and a lower force generating electrode 805. The upper force generating electrode 804 may be located directly above the lower force generating electrode 805. The upper force generating electrode 804 may be located directly below the ground electrode 803. Both the upper force generating electrode 804 and the lower force generating electrode 805 may be located close to a substrate facing edge of the substrate shaping device 802. The upper force generating electrode 804 may be provided on, or embedded within, an upper surface of part of the substrate shaping device 802. The lower force generating electrode 805 may be provided on, or embedded within, an lower surface of part of the substrate shaping device 802.

A controller (not shown) may generate a potential difference between the ground electrode 803 and the upper force generating electrode 804 and/or the lower force generating electrode 805. This results in an electrostatic force being applied to the substrate W by the upper force generating electrode 804 and/or the lower force generating electrode 805. The upper force generating electrode 804 may be positioned further away from the support surface than the upper surface of the substrate W. The lower force generating electrode 804 may be positioned closer to the support surface than the lower surface of the substrate W. The electrostatic forces applied to the periphery of the substrate W by the upper force generating electrode 804 and the lower force generating electrode 805 may both comprise an x-y-directed component and a z-directed component. The z-directed component of the electrostatic force applied by the upper force generating electrode 804 may act to move the periphery of the substrate W away from the support plane. The z-directed component of the electrostatic force applied by the lower force generating electrode 804 may act to move the periphery of the substrate W towards from the support plane. Accordingly, the upper force generating electrode 804 and the lower force generating electrode 805 may be used to apply a force to the periphery of the substrate W that respectively moves the periphery of the substrate W either away form or towards the support plane. As described for the first embodiment, the substrate support arrangement may comprise a controller that is arranged to control the magnitude of a potential difference between the ground electrode 803 and the upper force generating electrode 804 and/or lower force generating electrode 805.

In a preferred implementation of the second embodiment, the upper force generating electrode 804 is positioned so that the direction of the electrostatic force applied by the upper force generating electrode 804 to the periphery of the substrate W is at an angle of about 80° to the plane of the support surface. The lower force generating electrode 805 is also preferably positioned so that the direction of the electrostatic force applied by the lower force generating electrode 805 to the periphery of the substrate W is at an angle of about 80° to the plane of the support surface.

The ground electrode 803 may be at least partially on an upper surface of the substrate shaping device 802. The ground electrode 803 may be substantially coplanar with an upper surface of the substrate W.

In the present embodiment, there is a seal 807 that covers at least part of the substrate shaping device 802 and the substrate W. The seal 807 may extend in the x-y-direction from above the substrate shaping device 802 to above the upper surface of the substrate W. The seal 807 may be a liquid seal that substantially prevents any immersion fluid that is on the upper surface of the substrate W from flowing over the edge of the substrate W. The seal 807 ensures that there is substantially no immersion fluid between the periphery of the substrate W and either the upper force generating electrode 804 or the lower force generating electrode 805.

The substrate shaping system 800 may comprise a plurality of substrate shaping devices 802. In plan view, the plurality of substrate shaping devices 802 may be arranged around the support surface. The plurality of substrate shaping devices 802 may be equally spaced around the circumference of the support surface. Each substrate shaping device 802 may be arranged to apply an electrostatic force to a different segment of a substrate W. The substrate shaping devices 802 may be independently controllable. The substrate shaping devices 802 may thereby be arranged to independently apply electrostatic forces to different parts of the periphery of the substrate W.

As described for the first embodiment, each substrate shaping device 802 may be moveable between a first position and a second position. In the first position, a substrate shaping device 802 may be located close to the periphery of a substrate W so that it may apply an electrostatic force to the periphery of the substrate W. The second position of each substrate shaping device 802 may be located further away from a mid-point of the substrate support 20 so that a substrate W may be easily positioned on the substrate support 20. Each substrate shaping device 802 may therefore be moved to its second position during the loading and unloading of a substrate W, and moved to its first position when a substrate W is loaded on the substrate support 20.

FIG. 6 schematically shows a substrate shaping device 802 in the first position. There is a x-y-directed separation distance 806, that may be referred to as a lateral gap, between the edge of the substrate W and the substrate facing edge of the substrate shaping device 802.

For movement between the first and second positions, each substrate shaping device 802 may be moveable relative to the substrate support 20 in a direction parallel to the plane of the support surface, i.e. in a direction that increases, or decreases, the x-y-directed separation distance 806. Each substrate shaping device 802 may be located on a base 801 that comprises one or more piezoelectric actuators (not shown) for moving the substrate shaping device 802 relative to the substrate support 20.

As described for the first embodiment, in order to determine an appropriate first position for each substrate shaping device 802, the substrate shaping system 800 may comprise a sensor system (not shown) configured to determine the relative position of each substrate shaping device 802 and the substrate W. For example, the sensor system may determine the magnitude of the x-y-directed separation distance 806. The sensor system may comprise one or more capacitors and/or light sources for determining/measuring the magnitude of the x-y-directed separation distance 806. An appropriate first position of each substrate shaping device 802 may be determined as a location at which the magnitude of the x-y-directed separation distance 806 is within a predetermined range. For example, the movement of each substrate shaping device 802 may be controlled, by a controller, so that its x-y-directed separation distance 806 is less than or equal to 10 μm.

FIG. 7 schematically shows part of a seal 807 according to an embodiment. The seal 807 may be a mechanical edge seal (MES). The seal 807 may comprise a groove 901 in its substrate facing surface. Immersion fluid, that may be water, may be present in a fluid region 903 above the substrate W. Due to surface tension, a meniscus of 902 the immersion fluid forms at the edge of the groove 901 so that the immersion fluid does not flow further along the length of the seal 807. The groove 901 therefore provides a capillary stop. Advantageously, the seal 807 does not physically contact the substrate W. In addition, the presence of the seal 807 reduces the amount of immersion fluid flowing over the edge of the substrate W and thereby reduces both the thermal load, and the variation of thermal load, that each substrate W experiences. Additionally, or alternatively, the region below the periphery of the substrate W may be supplied with gas to increase the gas pressure. The overpressure of gas may reduce, or prevent, the flow of immersion liquid over the edge of the substrate W.

The seal 807 may be static or moveable. A static seal 807 may be, in plan view, a single annular structure that covers the entire circumference of the substrate W. When a static seal 807 is used, the seal 807 may retain its relative position to the substrate W when each substrate shaping device 802 moves between its first and second positions. An independent mechanism may be used to position the static seal 807 above a substrate W after the substrate W has been loaded on the substrate support 20. The same mechanism may be used to move the static seal 807 from above the substrate W before the substrate W is unloaded.

Alternatively, to provide a moveable seal 807, a seal 807 may be secured to each substrate shaping device 802. The shape of each seal 807 may be, in plan view, a truncated sector of a circle. Each seal 807 may move with the substrate shaping device 802 that it is secured to as the substrate shaping device 802 moves between its first and second positions. When all of a plurality of substrate shaping devices 802 are in their first position, their seals 807 may contact each other so that, in plan view, they combine to form an annular seal around the circumference of the substrate W.

In a similar manner to the first embodiment, in the second embodiment one or more further force generating electrodes 808 may be provided on the surface of, or embedded in, the substrate support 20 and/or a surrounding structure of the substrate support 20. The one or more further force generating electrodes 808 may be positioned so that, when a substrate W is loaded on the substrate support 20, the one or more further force generating electrodes 808 are located below the periphery of the substrate W. There may be a plurality of the further force generating electrodes 808.

In plan view, the plurality of further force generating electrodes 808 may be arranged around the support surface. The plurality of further force generating electrodes 808 may be equally spaced around the circumference of the support surface. Each further force generating electrode 808 may be arranged to apply an electrostatic force to a different segment of a substrate W. The plurality of further force generating electrodes 808 may be independently controllable. The further force generating electrodes 808 may thereby be arranged to independently apply electrostatic forces to different parts of the periphery of the substrate W.

Each of the one or more further force generating electrodes 808 may be electrically insulated. The substrate support 20 and/or a surrounding structure of the substrate support 20 may be electrically grounded. For each of the one or more further force generating electrodes 808, a potential difference may be generated between the force generating electrode 808 and ground. Each further force generating electrode 808 may apply an electrostatic force to the substrate W with the applied force being dependent on the potential difference. A controller may control each potential difference to thereby control the applied electrostatic force by each of the one or more further force generating electrodes 808.

Accordingly, the one or more further force generating electrodes 808 may generate electrostatic forces for moving the substrate W towards the substrate support 20.

The above-described embodiments provide a new technique for at least partially correcting the shape deformation of a substrate W. Electrostatic forces may be applied to the periphery of a substrate W to change the shape of the substrate W so as to reduce the shape deformation of the substrate W. The techniques of embodiments may be applied in both EUV and DUV systems.

Embodiments include a number of modifications and variations to the above described techniques.

In both the first and second embodiments, the provision of force generating electrodes 703, 808 on the surface of, or embedded in, the substrate support 20 and/or a surrounding structure of the substrate support 20 is optional. The at least partial correction of an umbrella shape deformation of a substrate W would still be possible.

In the second embodiment, the provision of the lower force generating electrode 805 is optional. The electrode arrangement of each substrate shaping device 802 may only comprise ground electrode 803 and the upper force generating electrode 804.

The use of a capillary stop in the seal 807 is optional. The seal 807 may alternatively contact the upper surface of the substrate W.

The substrate shaping device 701 shown in FIG. 5 may be adapted so that the end of the part that overhangs the substrate W comprises a groove (not shown). The groove may be similar to the groove 901 described with reference to FIG. 7 and it may therefore be a capillary stop. There is no need for a capillary stop in a vacuum system, such as an EUV system, because there is no liquid on the surface of the substrate W. However, providing the substrate shaping device 701 with a capillary stop may allow the same substrate shaping device 701 to be used in both EUV and DUV systems.

The burl arrangement shown in FIG. 2 is exemplary. Embodiments include the number of burls 22, 41 that protrude from the surface that faces the substrate W being much larger than the number of burls that are directed away from the substrate W.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of object inspection and/or optical lithography, it will be appreciated that the invention, where the context allows, is not limited to these contexts and may be used in other applications, for example imprint lithography.

Embodiments include the following numbered clauses:
1. A substrate support arrangement configured to support a substrate, the substrate support arrangement comprising:
   a substrate support with a substantially planar support surface for a substrate; and
   a substrate shaping system that comprises one or more substrate shaping devices;
   wherein each substrate shaping device is moveable relative to the substrate support; and
   wherein, when a substrate is provided on the support surface, each substrate shaping device is arranged to apply an electrostatic force to the periphery of the substrate.
2. The substrate support arrangement according to clause 1, wherein each substrate shaping device is arranged to move relative to the substrate support in a direction parallel to the plane of the support surface.
3. The substrate support arrangement according to clause 1 or 2, wherein each substrate shaping device is arranged to move relative to the substrate support in a direction perpendicular to the plane of the support surface.
4. The substrate support arrangement according to any preceding clause, wherein the substrate shaping system comprises a plurality of substrate shaping devices and, in plan view, the plurality of substrate shaping devices are arranged around the support surface.
5. The substrate support arrangement according to any preceding clause, further comprising one or more piezoelectric actuators;
   wherein each piezoelectric actuator is arranged to move at least one substrate shaping device relative to the substrate support.
6. The substrate support arrangement according to any preceding clause, wherein each substrate shaping device comprises an electrode arrangement configured to generate the electrostatic force applied by the substrate shaping device.
7. The substrate support arrangement according to clause 6, wherein the electrode arrangement comprises a ground electrode and a force generating electrode; and
the ground electrode and the force generating electrode are arranged such that, when a substrate is provided on the support surface, the electrostatic force is generated between the force generating electrode and the periphery of the substrate.
8. The substrate support arrangement according to clause 7, further comprising a controller arranged to control the magnitude of a potential difference between the ground electrode and the force generating electrode of each substrate shaping device to thereby control the magnitude of the electrostatic force applied by the substrate shaping device.
9. The substrate support arrangement according to clause 7 or 8, wherein the force generating electrode is arranged such that, when a substrate is provided on the support surface, the electrostatic force applied by each substrate shaping device comprises a component that is perpendicular to the plane of the support surface and is directed so as to move the substrate away from the support surface.
10. The substrate support arrangement according to any of clauses 7 to 9, wherein the force generating electrode is arranged such that, when a substrate is provided on the support surface, the electrostatic force applied by each substrate shaping device is directed at an angle of about 90° to the plane of the support surface.
11. The substrate support arrangement according to any of clauses 7 to 9, wherein the force generating electrode is arranged such that, when a substrate is provided on the support surface, the electrostatic force applied by each substrate shaping device is directed at an angle of about 80° to the plane of the support surface.
12. The substrate support arrangement according to any of clauses 7 to 11, wherein the force generating electrode of each substrate shaping device is embedded within the substrate shaping device.
13. The substrate support arrangement according to any of clauses 7 to 12, wherein the ground electrode of each substrate shaping device is located on an upper surface of the substrate shaping device.
14. The substrate support arrangement according to any of clauses 7 to 13, wherein each substrate shaping device comprises more than one force generating electrode; and
at least one force generating electrode is arranged such that, when a substrate is provided on the support surface, the electrostatic force applied by each substrate shaping device comprises a component that is perpendicular to the plane of the support surface and is directed so as to move the substrate towards the support surface.
15. The substrate support arrangement according to any preceding clause, wherein, when a substrate is provided on the support surface, a lateral gap is formed between the edge of the substrate and the edge of each substrate shaping device.
16. The substrate support arrangement according to clause 15, further comprising a sensor system configured to measure the size of each lateral gap.
17. The substrate support arrangement according to clause 16, further comprising a controller configured to control the movement of each substrate shaping device in dependence on the measured size of each lateral gap.
18. The substrate support arrangement according to clause 17, wherein the controller is configured to control the movement of each substrate shaping device so that each lateral gap is less than or equal to 10 μm.
19. The substrate support arrangement according to any of clauses 15 to 18, wherein, when a substrate is provided on the support surface, an upper surface of each substrate shaping device is substantially co-planar with an upper surface of the substrate.
20. The substrate support arrangement according to clause 19, further comprising one or more seals;
wherein each seal is arranged such that, when a substrate is provided on the support surface, each seal spans the lateral gap formed between the edge of the substrate and the edge of each substrate shaping device.
21. The substrate support arrangement according to clause 20, wherein, when a substrate is provided on the support surface, each seal is arranged so that it does not contact the substrate.
22. The substrate support arrangement according to clause 20 or 21, wherein, when a substrate is provided on the support surface, each seal comprises a capillary stop.
23. The substrate support arrangement according to any of clauses 1 to 14, wherein, when a substrate is provided on the support surface, each substrate shaping device is moved so that a vertical gap is formed between an upper surface of the substrate and a lower surface of each substrate shaping device.
24. The substrate support arrangement according to clause 23, further comprising a sensor system configured to measure the size of each vertical gap.
25. The substrate support arrangement according to clause 24, further comprising a controller configured to control the movement of each substrate shaping device in dependence on the measured size of each vertical gap.
26. The substrate support arrangement according to clause 25, wherein the controller is configured to control the movement of each substrate shaping device so that each vertical gap is less than or equal to 10 μm.
27. The substrate support arrangement according to any preceding clause, further comprising one or more further force generating electrodes embedded in the substrate support and/or a surrounding structure of the substrate support;
wherein the one or more further force generating electrodes are arranged such that, when a substrate is provided on the support surface, each of the one or more further force generating electrodes is arranged to apply an electrostatic force to the periphery of the substrate; and
each electrostatic force comprises a component that is perpendicular to the plane of the support surface and is directed so as to move the substrate towards the support surface.
28. The substrate support arrangement according to clause 27, wherein there are a plurality of further force generating electrodes embedded in the substrate support and/or a surrounding structure of the substrate support and, in plan view, the plurality of further force generating electrodes are arranged around the support surface.
29. A lithographic apparatus comprising the substrate support arrangement according to any preceding clause.
30. A method of changing the shape of a substrate, the method comprising:
loading a substrate onto the substrate support of a substrate support arrangement according to any of clauses 1 to 28; and
applying an electrostatic force to the periphery of the substrate.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A substrate support arrangement configured to support a substrate, the substrate support arrangement comprising:
a substrate support with a substantially planar support surface for a substrate; and
a substrate shaping system that comprises one or more substrate shaping devices,
wherein each substrate shaping device is moveable relative to the substrate support; and
wherein, when a substrate is provided on the support surface, each substrate shaping device is arranged to apply an electrostatic force to the periphery of the substrate.

2. The substrate support arrangement according to claim 1, wherein each substrate shaping device is arranged to move relative to the substrate support in a direction parallel to the plane of the support surface.

3. The substrate support arrangement according to claim 1, wherein each substrate shaping device comprises an electrode arrangement configured to generate the electrostatic force applied by the substrate shaping device.

4. The substrate support arrangement according to claim 3, wherein the electrode arrangement comprises a ground electrode and a force generating electrode; and
the ground electrode and the force generating electrode are arranged such that, when a substrate is provided on the support surface, the electrostatic force is generated between the force generating electrode and the periphery of the substrate.

5. The substrate support arrangement according to claim 4, further comprising a controller arranged to control the magnitude of a potential difference between the ground electrode and the force generating electrode of each substrate shaping device to thereby control the magnitude of the electrostatic force applied by the substrate shaping device.

6. The substrate support arrangement according to claim 5, wherein the force generating electrode of each substrate shaping device is embedded within the substrate shaping device.

7. The substrate support arrangement according to claim 1, wherein, when a substrate is provided on the support surface, a lateral gap is formed between the edge of the substrate and the edge of each substrate shaping device.

8. The substrate support arrangement according to claim 7, further comprising a sensor system configured to measure the size of each lateral gap.

9. The substrate support arrangement according to claim 8, further comprising one or more seals, wherein each seal is arranged such that, when a substrate is provided on the support surface, each seal spans the lateral gap formed between the edge of the substrate and the edge of each substrate shaping device.

10. The substrate support arrangement according to claim 9, wherein, when a substrate is provided on the support surface, each seal is arranged so that it does not contact the substrate, and/or wherein, when a substrate is provided on the support surface, each seal comprises a capillary stop.

11. The substrate support arrangement according to claim 1, wherein, when a substrate is provided on the support surface, each substrate shaping device is moved so that a vertical gap is formed between an upper surface of the substrate and a lower surface of each substrate shaping device.

12. The substrate support arrangement according to claim 11, further comprising a sensor system configured to measure the size of each vertical gap.

13. The substrate support arrangement according to claim 1, further comprising one or more further force generating electrodes embedded in the substrate support and/or a surrounding structure of the substrate support,
wherein the one or more further force generating electrodes are arranged such that, when a substrate is provided on the support surface, each of the one or more further force generating electrodes is arranged to apply an electrostatic force, to the periphery of the substrate, that comprises a component that is perpendicular to the plane of the support surface and is directed so as to move the substrate towards the support surface.

14. A lithographic apparatus comprising the substrate support arrangement according to claim 1.

15. A method comprising:
loading a substrate onto a substrate support of a substrate support arrangement, the substrate support arrangement comprising a substrate shaping system that comprises one or more substrate shaping devices;
moving each of the one or more substrate shaping devices relative to the substrate support; and
applying an electrostatic force to the periphery of the substrate using the one or more substrate shaping devices.

16. The substrate support arrangement according to claim 1, wherein each substrate shaping device is arranged to move relative to the substrate support in a direction perpendicular to the plane of the support surface.

17. The substrate support arrangement according to claim 1, wherein the substrate shaping system comprises a plurality of substrate shaping devices and, in plan view, the plurality of substrate shaping devices are arranged around the support surface.

18. The substrate support arrangement according to claim 4, wherein the force generating electrode is arranged such that, when a substrate is provided on the support surface, the electrostatic force applied by each substrate shaping device comprises a component that is perpendicular to the plane of the support surface and is directed so as to move the substrate away from the support surface.

19. The substrate support arrangement according to claim 4, wherein the ground electrode of each substrate shaping device is located on an upper surface of the substrate shaping device.

20. The substrate support arrangement according to claim 4, wherein each substrate shaping device comprises more than one force generating electrode; and at least one force generating electrode is arranged such that, when a substrate is provided on the support surface, the electrostatic force applied by each substrate shaping device comprises a component that is perpendicular to the plane of the support surface and is directed so as to move the substrate towards the support surface
